(19) United States
(12) Patent Application Publication
(10) Pub. No.: US 2010/0078211 A1
(43) Pub. Date: Apr. 1, 2010

(54) Memory module and topology of circuit board

(75) Inventors: Dohyung Kim, Yongin-si (KR); Jung-Mo Yang, Gwangmyeong-si (KR); Hyunjung Yoo, Seoul (KR); Dong-Yoon Seo, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/461,799

(22) Filed: Aug. 25, 2009

(30) Foreign Application Priority Data
Oct. 1, 2008 (KR) 10-2008-0096695

(51) Int. Cl. H05K 1/11

(52) U.S. Cl. 174/262

(57) ABSTRACT

Provided is a module having a symmetric topology. The module may include a pair of diverging via bodies configured to receive complementary signals. The pair of diverging via bodies may be further configured to diverge the complementary signals in at least three pairs of diverged complementary signals. The module may further include at least three pairs of connecting via bodies configured to receive the at least three pairs of diverged complementary signals from the pair of diverging via bodies and configured to transmit the at least three pairs of diverged complementary signals to components.

### CROSS-REFERENCE TO RELATED APPLICATIONS

This patent application claims priority under 35 U.S.C. §119 to Korean Patent Application No. 10-2008-0096695, filed on Oct. 1, 2008, in the Korean Intellectual Property Office (KIPO), the entire contents of which are herein incorporated by reference.

### BACKGROUND

1. Field

Example embodiments disclosed herein relate to a memory module and a topology of circuit board.

2. Description of the Related Art

Semiconductor devices may be highly integrated, departmentalized, and miniaturized and may operate at relatively high speeds. Circuit board designs used in a semiconductor device are relatively important in order to assure the semiconductor devices work properly. In particular, circuit boards should be designed to prevent or reduce signal distortions.

Conventional circuit boards may use signal interconnections disposed on a multilayer. Conventional circuit boards may also use signal interconnections disposed on different layers. The various signal interconnections may be electrically connected to each other through vias. However, because controlling an impedance characteristic of a via is difficult, a signal distortion may occur. For example, in a case of a single ended signal arrangement, a capacitance or an inductance of a via may be changed due to its arrangement with respect to a reference layer. Also, a differential signal arrangement may transmit a signal with a complementary signal using an adjacent pair of signal interconnections.

### SUMMARY

In accordance with example embodiments, a module may include a pair of diverging via bodies configured to receive complementary signals. The pair of diverging via bodies may be further configured to diverge the complementary signals in at least three pairs of diverged complementary signals. In accordance with example embodiments, the module may further include at least three pairs of connecting via bodies configured to receive the at least three pairs of diverged complementary signals from the pair of diverging via bodies and configured to transmit the at least three pairs of diverged complementary signals to components.

Example embodiments also provide a memory module that may include a pair of diverging vias receiving complementary signals to diverge in at least three pairs of complementary signals, and a pair of connecting vias receiving at least the three pairs of diverged complementary signals from the pair of diverging vias to transmit the complementary signals to respective components. The complementary signals may be transmitted to the respective components by the same topology.

Example embodiments also provide a topology of a circuit board. The topology may include a first diverging point receiving a first signal, a second diverging point receiving a second signal complementary to the first signal, a plurality of first connecting points diverging from the first diverging point in at least three to be connected to components respectively, and a plurality of second connecting points diverging from the second diverging point in at least three to be connected to components respectively. The first connecting points may be connected to different components respectively and the second connecting points may be connected to different components respectively.

### BRIEF DESCRIPTION OF THE FIGURES

Example embodiments will be more clearly understood from the following detailed description taken in conjunction with the accompanying drawings. FIGS. 1-8 represent non-limiting, example embodiments as described herein.

FIG. 1 is a drawing illustrating a topology diverging in three pairs of differential signals according to example embodiments.

FIG. 2 illustrates the topology depicted in FIG. 1 in three dimensions.

FIG. 3 is a drawing illustrating a topology diverging in four pairs of differential signals according to example embodiments.

FIG. 4 illustrates the topology depicted in FIG. 3 in three dimensions.

FIG. 5 is a drawing illustrating an embodiment of a design of an Unregistered Dual In-Line Memory Module (UDIMM) of four layers.

FIG. 6 is a drawing of a topology illustrating a clock divergence.

FIG. 7 is a drawing illustrating a structure of a conventional differential signal embodied in a structure of FIG. 6(d).

FIG. 8 is a drawing illustrating a structure of a conventional differential signal embodied in a topology structure according to example embodiments.

### DETAILED DESCRIPTION OF EXAMPLE EMBODIMENTS

Example embodiments will now be described more fully with reference to the accompanying drawings, in which example embodiments are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the sizes of components may be exaggerated for clarity.

It will be understood that when an element or layer is referred to as being “on”, “connected to”, or “coupled to” another element or layer, it can be directly on, connected to, or coupled to the other element or layer or intervening elements or layers that may be present. In contrast, when an element is referred to as being “directly on”, “directly connected to”, or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. Thus, a first element, component, region, layer, or section discussed below could be termed a second element, component, region, layer, or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes or regions of elements, and do not limit example embodiments.

A circuit board according to example embodiments may use a topology of a physically symmetrical structure so as to diverge in at least three pairs of signals on the same layer. Accordingly, a circuit board according to example embodiments may have a relatively low cost and a relatively improved signal transmission characteristic compared with a conventional circuit board. A circuit board according to example embodiments may be a printed circuit board (PCB), a flexible PCB (FPCB), a flexible rigid PCB (FRPCB), and/or a ceramic substrate but is not limited to the aforementioned description. For convenience, a printed circuit board may be used in a detailed description below. A circuit board according to example embodiments may be used as a package substrate, a substrate of a multi-chip module, and/or a mother board but is not limited to the aforementioned uses.

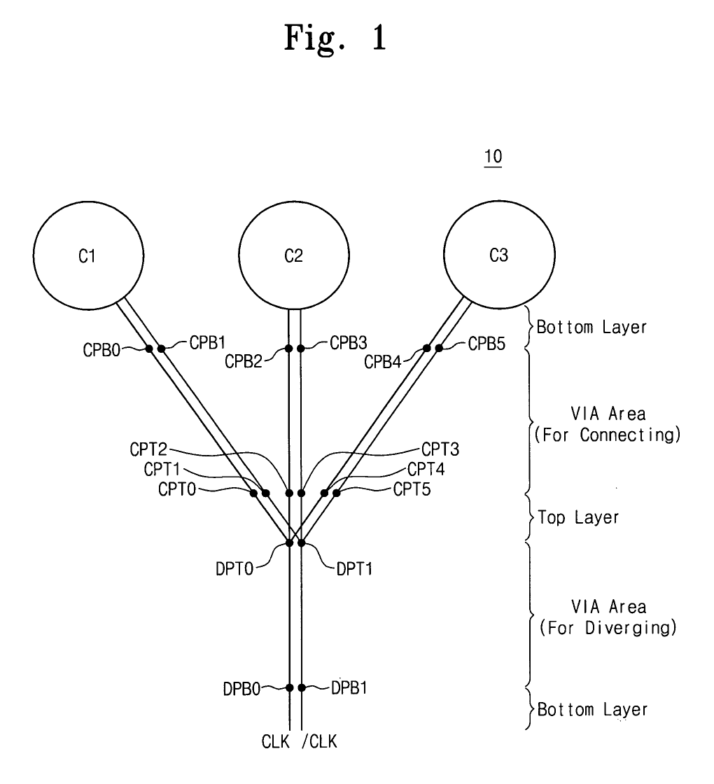

FIG. 1 is a drawing illustrating a topology diverging in three pairs of differential signals according to example embodiments. Referring to FIG. 1, a topology may have a symmetrical structure. In particular, three pairs of differential signal interconnections may have the physically same structure. The physically same structure may include a topology, a length, and/or a layer.

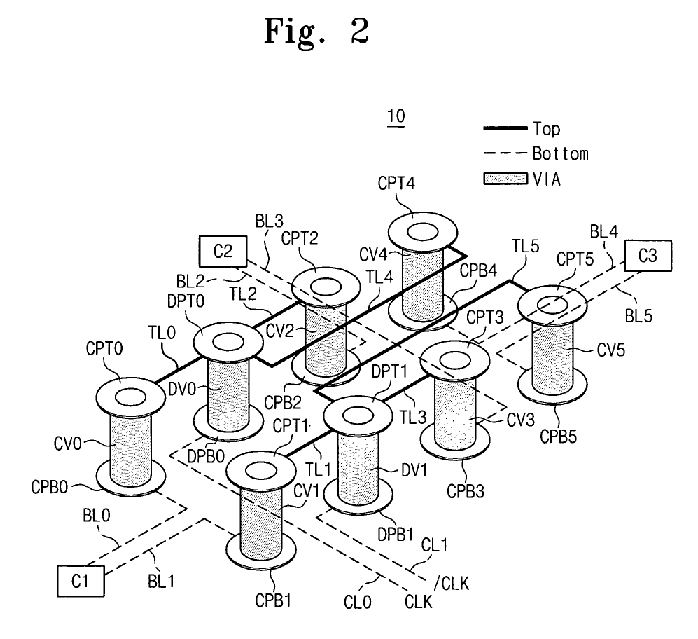

A via, as is known in the art, is a hole passing through a layer. The via may be filled with a conductive material or may be lined with a conductive material so that a signal may be transmitted from one end of the via to another end of the via. As used in this specification, a via body refers to the conductive material filling or lining a via hole. As shown in FIG. 2, example embodiments provide for a topology which includes eight via bodies. Two of these via bodies (DV0, DV1) may diverge a signal and are therefore referred to as diverging via bodies (DV0, DV1) and six of the via bodies may connect the diverging via bodies (DV0, DV1) to various components and are therefore referred to as connecting via bodies (CV0, CV1, CV2, CV3, CV4, CV5).

In example embodiments, for example, in a case of a topology, a clock signal (CLK) may travel through four diverging points until the clock signal (CLK) is transmitted to a first component (C1), a second component (C2) and/or a third component (C3) respectively.

In accordance with example embodiments, a clock signal (CLK) transmitted to the first component (C1) may be transmitted from a diverging point (DPB0) to a diverging point (DPT0), from the diverging point (DPT0) to a diverging point (CPT0), and from the diverging point (CPT0) to a diverging point (CPB0). A clock signal (CLK) transmitted to the second component (C2) may be transmitted from a diverging point (DPB0) to a diverging point (DPT0), from the diverging point (DPT0) to a diverging point (CPT2), and from the diverging point (CPT2) to a diverging point (CPB2). A clock signal (CLK) transmitted to the third component (C3) may be transmitted from a diverging point (DPB0) to a diverging point (DPT0), from the diverging point (DPT0) to a diverging point (CPT4), and from the diverging point (CPT4) to a diverging point (CPB4).

As shown in FIG. 2, the diverging point (DPT0) may correspond to a first diverging element which may be, for example, a substrate pad covering a top portion of the diverging via body (DV0). However, example embodiments are not limited thereto. For example, the diverging point (DPT0) may correspond to a top portion of the diverging via body (DV0) that may be exposed. Accordingly, an exposed top surface of the diverging via body (DV0) may correspond to a first diverging element. Similarly, the diverging point (DPB0) may correspond to a third diverging element, for example, a substrate pad, that may cover or contact a bottom portion of the diverging via body (DV0). However, example embodiments are not limited thereto. For example, a bottom portion of the diverging via body (DV0) may be exposed. Accordingly, an exposed bottom portion of the diverging via body (DV0) may correspond to the third diverging element.

As shown in FIG. 2, the diverging points (CPT0, CPT2, and CPT4) may correspond to a first plurality of first conductive elements, for example, substrate pads, that may cover or contact a top portion of the connecting via bodies (CV0, CV2, CV4). However, example embodiments are not limited thereto. For example, top portions of the connecting via bodies (CV0, CV2, CV4) may be exposed, accordingly, the exposed top portions of connecting via bodies (CV0, CV2, CV4) may correspond to the first plurality of first conductive elements. Similarly, the diverging points (CPB0, CPB2, and CPB4) may correspond to a second plurality of first conductive elements, for example, substrate pads, that may cover or contact a bottom portion of the connecting via bodies (CV0, CV2, CV4). However, example embodiments are not limited thereto. For example, bottom portions of the connecting via bodies (CV0, CV2, CV4) may be exposed. Accordingly, the exposed bottom portions of connecting via bodies (CV0, CV2, CV4) may correspond to the second plurality of first conductive elements.

In accordance with example embodiments, a clock bar signal (/CLK) may travel through four diverging points until the clock bar signal (/CLK) is transmitted to respective components (C1,C2, C3). For example, a clock bar signal (/CLK) transmitted to the first component (C1) may be transmitted from a diverging point (DPB1) to a diverging point (DPT1), from the diverging point (DPT1) to a diverging point (CPT1), and from the diverging point (CPT1) to a diverging point (CPB1). A clock bar signal (/CLK) transmitted to the second component (C2) may be transmitted from a diverging point (DPB1) to a diverging point (DPT1), from the diverging point (DPT1) to a diverging point (CPT3), and from the diverging point (CPT3) to a diverging point (CPB3). A clock bar signal (/CLK) transmitted to the third component (C3) may be transmitted from a diverging point (DPB1) to a diverging point (DPT1), from the diverging point (DPT1) to a diverging point (CPT5), and from the diverging point (CPT5) to a diverging point (CPB5).

As shown in FIG. 2, the diverging point (DPT1) may correspond to a second diverging element which may be, for example, a substrate pad that may cover or contact a top portion of the diverging via body (DV1). However, example embodiments are not limited thereto. For example, a top portion of the diverging via body (DV1) may be exposed. Accordingly, the exposed top portion of diverging via body (DV1) may correspond to the second diverging element. Similarly, the diverging point (DPB1) may correspond to a fourth diverging element, for example, a substrate pad, that may cover or contact a bottom portion of the diverging via body (DV1). However, example embodiments are not limited thereto. For example, a bottom portion of the diverging via body (DV1) may be exposed. Accordingly, the exposed bottom portion of diverging via body (DV1) may correspond to the fourth diverging element.

As shown in FIG. 2, the diverging points (CPT1, CPT3, CPT5) may correspond to a first plurality of second conductive elements, for example, substrate pads, that may cover or contact the connecting via bodies (CV1, CV3, CV5). However, example embodiments are not limited thereto. For example, top portions of the connecting via bodies (CV1, CV3, CV5) may be exposed and the exposed top portions of connecting via bodies (CV1, CV3, CV5) may correspond to the first plurality of second conductive elements. The diverging points (CPB1, CPB3, CPB5) may correspond to a second plurality of second conductive elements, for example, substrate pads, that may cover or contact bottom surfaces of the connecting via bodies (CV1, CV3, CV5). However, example embodiments are not limited thereto. For example, bottom portions of the connecting via bodies (CV1, CV3, CV5) may be exposed and the exposed bottom portions of connecting via bodies (CV1, CV3, CV5) may correspond to the second plurality of second conductive elements.

In accordance with example embodiments, the clock signal (CLK) and the clock bar signal (/CLK) may be complementary signals.

As described above, the clock signal (CLK) and the clock bar signal (/CLK) of example embodiments may travel through the same number of diverging points until the clock signal (CLK) and the clock bar signal (/CLK) are transmitted to respective components (C1, C2, C3). Going through the same number of diverging points may considerably reduce a signal difference between the respective components (C1, C2, C3). The considerable reduction of the signal difference may be relatively significant because a signal delay and a signal distortion at a diverging point may be relatively large compared to other factors (for example, a length, and/or layer).

With regard to length, distances from diverging points (DPT0, DPT1), from which the clock signal (CLK) and the clock bar signal (/CLK) diverge, to the respective components (C1, C2, C3) may be approximately equal to each other. This does not mean that distances between a diverging point and a diverging point are equal to each other but means that whole distances are approximately equal to each other. The same distance may bring about the same signal delay. Thus, a signal difference between the clock signal (CLK) and the clock bar signal (/CLK) transmitted to the respective components (C1, C2, C3) may be reduced or minimized.

With respect to a layer, a signal divergence may be performed on the same layer. For convenience, the clock signal (CLK) and the clock bar signal (/CLK) may be considered first complementary signals. As depicted in FIGS. 1 and 2, a clock signal divergence may be performed on a top layer having diverging points (DPT0, DPT1, CPT0-CPT5). Signal lines (TL0-TL5) for a signal divergence may be included in the top layer. In example embodiments, a signal divergence may be performed on the same layer. Thus, a signal distortion in example embodiments may be relatively small compared with a signal distortion when a signal divergence is performed on a different layer.

A bottom layer may include clock lines (CL0, CL1 of FIG. 2) used to transmit received clock signal (CLK) and clock bar signal (/CLK) to respective diverging points (DPT0, DPT1) and signal lines (BL0-BL5 of FIG. 2) used to transmit clock signal (CLK) and clock bar signal (/CLK) transmitted to respective diverging points (CPB0-CPB5) to respective components (C1, C2, C3).

Referring to FIGS. 1 and 2, example embodiments use eight via bodies (DV0, DV1, CV0-CV5) to diverge in three pairs of differential signals. The via bodies (DV0, DV1 of FIG. 2) may be used to diverge a clock signal (CLK) and a clock bar signal (/CLK) and the via bodies (CV0-CV5 of FIG. 2) may be used to connect a diverged clock signal (CLK) and a diverged clock bar signal (/CLK) to the respective components (C1, C2, C3).

FIG. 2 illustrates the topology depicted of FIG. 1 in three dimensions. Referring to FIG. 2, respective components (C1, C2, C3) may receive a clock signal (CLK) and a clock bar signal (/CLK) diverged from a bottom layer and the received clock signal (CLK) and clock bar signal (/CLK) may be respectively diverged into three directions at diverging points (DPT0, DPT1) of a top layer. The diverging points (DPT0, DPT1) may be connected to one end of diverging via bodies (DV0, DV1) respectively. Diverging points (DPB0, DPB1) may be connected to the other end of the diverging via bodies (DV0, DV1), respectively. The clock signal (CLK) and the clock bar signal (/CLK) may be inputted to diverging points (DPB0, DPB1).

Referring back to FIG. 2, the diverging via bodies (DV0, DV1) may be spaced a predetermined or preset distance apart from each other. A pair of connecting via bodies (CV0, CV1) for being connected to the first component (C1), a pair of connecting via bodies (CV2, CV3) for being connected to the second component (C2), and a pair of connecting via bodies (CV4, CV5) for being connected to the third component (C3) may be disposed adjacent to, or near, the diverging via bodies (DV0, DV1). The pairs of connecting via bodies ((CV0, CV1), (CV2, CV3), (CV4, CV5)) may be spaced a predetermined or preset distance apart from each other.

The diverging via body (DV0) may be connected to the connecting via body (CV0) through a diverging point (DPT0) and a diverging point (CPT0), connected to the connecting via body (CV2) through the diverging point (DPT0) and a diverging point (CPT2), and connected to the connecting via body (CV4) through the diverging point (DPT0) and a diverging point (CPT4). Also, the diverging via body (DV1) may be connected to the connecting via body (CV1) through a diverging point (DPT1) and a diverging point (CPT1), connected to the connecting via body (CV3) through the diverging point (DPT1) and a diverging point (CPT3), and connected to the connecting via body (CV5) through the diverging point (DPT1) and a diverging point (CPT5).

A signal line (TL4) may connect the diverging point (DPT0) and the diverging point (CPT4) and a signal line (TL5) may connect the diverging point (DPT1) and the diverging point (CPT5). As shown in FIG. 2, the signal lines (TL4, TL5) may be disposed between the pairs of via bodies ((DV0, DV1), (CV2, CV3), (CV4, CV5)). Additionally, as shown in FIG. 2, the signal line (TL4) and the signal line (TL5) may have a structure symmetrical to each other.

The third component (C3) may be disposed near, or adjacent to, the second component (C2) as shown in FIG. 2, however, example embodiments are not limited thereto. For example, the third component (C3) may be disposed near, or adjacent to, the first component (C1).

Although the signal lines (TL4, TL5) may be between a pair of via bodies as shown in FIG. 2, example embodiments are not limited thereto. For example, signal lines (TL4, TL5) may be symmetrically disposed on the top layer so that the diverging point (DPT0) is connected to the diverging point (CPT4) and the diverging point (DPT1) is connected to the diverging point (CPT5), wherein the signal lines (TL4, TL5) are disposed outside of the pairs of via bodies.

The distance from the diverging points from which the clock/clock bar signals diverge to each of the components (C1, C2, C3) may be relatively uniform. For example, the distance traveled by the diverged clock signal (CLK) and the distance traveled by the diverged clock bar signal (/CLK) to the first component (C1) may be substantially the same. Similarly, the distance traveled by the diverged clock signal (CLK) and the diverged clock bar signal (/CLK) to the second component (C2) may be substantially the same. Likewise, the distance traveled by the diverged clock signal (CLK) and the diverged clock bar signal (/CLK) to the third component (C3) may be substantially the same.

In the conventional art, when a differential signal diverges from one diverging point in at least three pairs on a general circuit board, additional layers or additional vias may be needed because performing a design on the same layer may be difficult. In contrast, a circuit board using a topology of example embodiments may perform a diverging operation on the same layer with respect to a differential signal diverging in at least three pairs and does not need additional vias. Furthermore, because the number of diverging points may be physically the same, the whole distance may be the same and the differential signal may diverge on the same layer, the diverged signals may be relatively undistorted and an effect of a signal delay may be relatively small, reduced, or minimized.

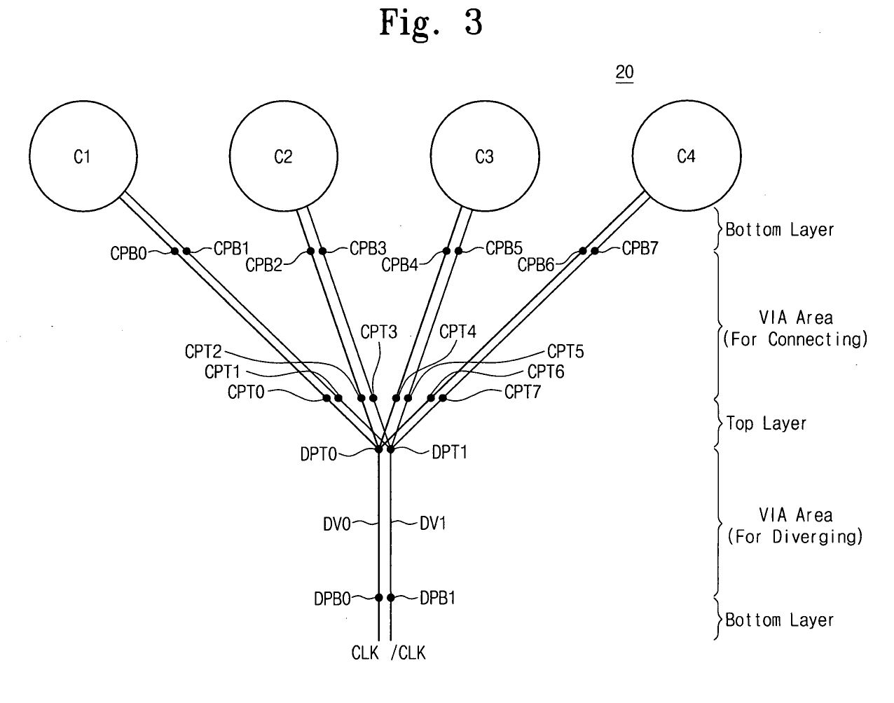

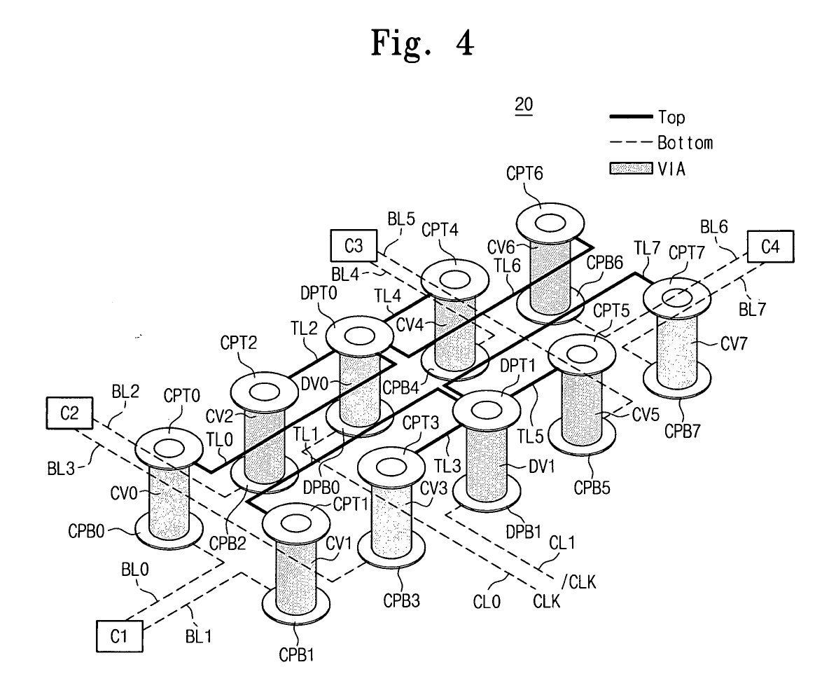

FIG. 3 is a drawing illustrating a topology 20 diverging in four pairs of differential signals according to example embodiments. FIG. 4 illustrates the topology 20 depicted in FIG. 3 in three dimensions. Referring to FIGS. 3 and 4, a topology 20 may further include a pair of connecting via bodies (CV6, CV7) for connecting diverged clock signal (CLK) and diverged clock bar signal (/CLK) to a fourth component (C4) compared with the topology 10 depicted in FIG. 1. Four signal lines (TL0, TL2, TL4, TL6) may diverge from a diverging point (DPT0) and four signal lines (TL1, TL3, TL5, TL7) may diverge from a diverging point (DPT1). As shown in FIG. 4, a pair of signal lines (TL0, TL1) and a pair of signal lines (TL6, TL7) may be disposed between pairs of via bodies. As described above, the topology of example embodiments may be applied to diverging in four pairs. Although example embodiments illustrate signal lines (TL0, TL1, TL6, TL7) as being between pairs of via bodies, example embodiments are not limited thereto. For example, in example embodiments signal lines (TL0, TL1, TL6, TL7) may be disposed outside of the pairs of via bodies.

The topologies in FIGS. 1 through 4 may be applied to a differential signal diverging in three pairs and a differential signal diverging in four pairs. However, example embodiments are not limited to a differential signal diverging in three pairs or diverging in four pairs. The topology of example embodiments may also be applied to differential signals diverging in at least three pairs.

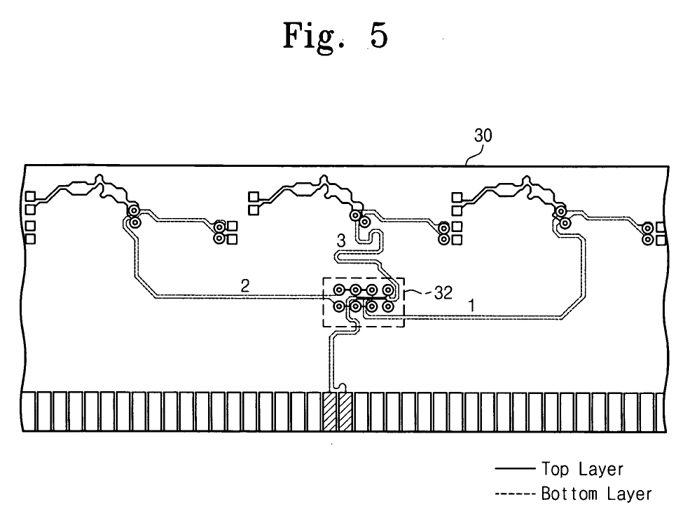

FIG. 5 is a drawing illustrating a design of UDIMM of four layers according to example embodiments. Referring to FIG. 5, a topology 30 of example embodiments may include a symmetrical topology diverging in three pairs of differential signals. Eight vias may be used in a diverging point 32. In FIG. 5, a dotted line is an interconnection made on a bottom layer (e.g., a first layer) and a solid line is an interconnection made on a top layer (e.g., a fourth layer). As depicted in FIG. 5, the distance through which an inputted signal passes until the inputted signal is transmitted to each component is uniform. That is, the sum of the dotted line and the solid line from the inputted signal to each component is uniform.

The DDR2 UDIMM of example embodiments may change a Joint Electron Device Engineering Council (JEDEC) basis design of six layers into a JEDEC basis design of four layers. All the UDIMM of JEDEC may have a clock diverging problem like below.

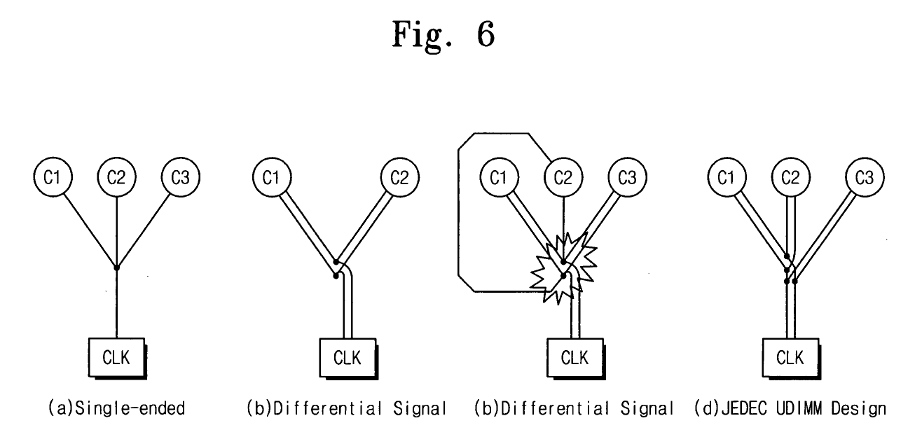

A single ended signal like FIG. 6(a) may diverge from a diverging point in a plurality of dynamic random access memories (DRAMs) without difficulty. However, in a case of a differential signal like FIG. 6(b), the differential signal may diverge in two through one via on the same signal layer but since additional vias or signal layers may be needed in a case that a differential signal diverges in at least three, a structure like FIG. 6(d) may be required.

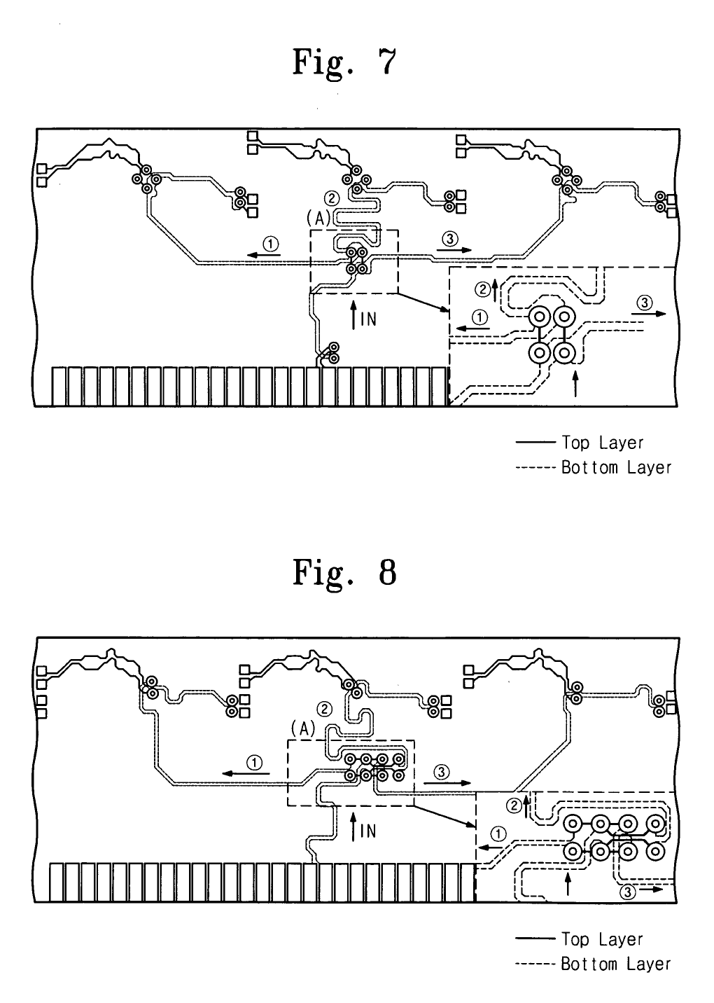

FIG. 7 is a drawing illustrating a structure of a conventional differential signal embodied in a structure of FIG. 6(d). Referring to FIG. 7, in a (A) region from which a clock diverges, a clock \textcircled{3} is connected to DRAM through one via but clocks \textcircled{1}/\textcircled{2} are connected to DRAM through two vias respectively. As a result, a skew is generated between clocks \textcircled{1}/\textcircled{2}/\textcircled{3}.

When a device operates at a high speed, the skew may become relatively great. Accordingly, a device may not operate at a target speed due to an insufficiency of a timing margin. If applying the same clock structure of JDEC to a four layer device for a cost reduction, the four layer device may be affected from vias more than two times compared with a six layer device because the four layer has only a top layer and a bottom layer as a signal layer and so a signal is transmitted from a top layer to a bottom layer through a via having a length equal to the whole thickness of PCB and, in a case of the six layer, a signal is transmitted from a top layer to a third layer or fourth layer through a via. For this reason, a 800 Mbps device, which may be a generation before D56, may be produced as the four layer device and a device higher than 1066 Mbps may be produced as the six layer device.

FIG. 8 is a drawing illustrating a structure of a differential signal embodied in a topology structure according to example embodiments. Referring to FIG. 8, when a clock diverges from (A) region in three, two clocks are arranged by a conventional method but a space is secured so that the clocks may pass between a pair of vias. One clock left passes between the diverging vias and thus, all of the clock signals have the physically same topology. As a result, a skew is reduced or minimized.

A power supply voltage plane may be included in an inner layer of a memory module embodied in a topology structure according to example embodiments. The inner layer being a layer disposed between a top layer and a bottom layer.

The above-disclosed subject matter is to be considered illustrative, and not restrictive, and the appended claims are intended to cover all such modifications, enhancements, and other embodiments, which fall within the true spirit and scope of example embodiments. Thus, to the maximum extent allowed by law, the scope of example embodiments is to be determined by the broadest permissible interpretation of the following claims and their equivalents, and shall not be restricted or limited by the foregoing detailed description.

What is claimed is:

1. A module comprising:
a pair of diverging via bodies configured to receive complementary signals, the pair of diverging via bodies further configured to diverge the complementary signals in at least three pairs of diverged complementary signals; and
at least three pairs of connecting via bodies configured to receive the at least three pairs of diverged complementary signals from the pair of diverging via bodies and configured to transmit the at least three pairs of diverged complementary signals to components.

2. The module of claim 1, wherein the at least three pairs of diverged complementary signals diverge on a same layer.

3. The module of claim 1, further comprising:
a first plurality of pairs of signal lines configured to transmit the at least three pairs of diverged complementary signals to the at least three pairs of connecting via bodies, wherein at least one pair of signal lines among the first plurality of pairs of signal lines is arranged between the pair of diverging via bodies and at least one pair of connecting via bodies among the at least three pairs of connecting via bodies.

4. The module of claim 3, wherein the first plurality of pairs of signal lines includes physically symmetric signal lines and distances of the complementary signals transmitted to the components are the same.

5. The module of claim 3, further comprising:
a second plurality of pairs of signal lines configured to transmit the at least three pairs of diverged complementary signals from the at least three pairs of connecting via bodies to the components.

6. The module of claim 1, wherein
the complementary signals include a clock signal and a clock bar signal and the pair of diverging via bodies is configured to diverge the clock signal and the clock bar signal into at least three diverged clock signals and at least three diverged clock bar signals,
the at least three pairs of diverged complementary signals include the at least three diverged clock signals and the at least three diverged clock bar signals such that each pair of the at least three pairs of diverged complementary signals includes one of the clock signals and one of the diverged clock bar signals and any one pair of the at least three pairs of diverged complementary signals is transmitted to any one pair of the at least three pairs connecting via bodies, and
the at least three diverged clock signals and the at least three diverged clock bar signals have a topology of a symmetric structure.

7. The module of claim 1, wherein the at least three pairs of diverged complementary signals is at least four pairs of diverged complementary signals and the at least three pairs of connecting via bodies is at least four pairs of connecting via bodies each configured to receive a pair of the at least four pairs of diverged complementary signals from the pair of diverging via bodies.

8. The module of claim 7, wherein
the complementary signals include a clock signal and a clock bar signal and the pair of diverging via bodies is configured to diverge the clock signal and the clock bar signal into at least four diverged clock signals and at least four diverged clock bar signals,
the at least four pairs of diverged complementary signals include the at least four diverged clock signals and the at least four diverged clock bar signals such that each pair of the at least four pairs of diverged complementary signals includes one diverged clock bar signal of the at least four diverged clock signals and one diverged clock bar signal of the at least four diverged clock bar signals and any one pair of the at least four pairs of diverged complementary signals is transmitted to any one pair of the at least four pairs connecting via bodies, and
the at least four pairs of diverged clock signals and the at least four pairs of diverged clock bar signals have a topology of a symmetric structure.

9. The module of claim 1, wherein the module includes a top layer including an arrangement for diverging the complementary signals in the at least three pairs of diverged complementary signals and a bottom layer including an arrangement for transmitting the at least three pairs of diverged complementary signals to the components.

10. The module of claim 9, wherein an inner layer of the module includes a power supply voltage plane.

11. The module of claim 1, further comprising:
a circuit board including a pair of diverging via holes configured to enclose the pair of diverging via bodies and at least three pairs of connecting via holes configured to enclose the at least three pairs of connecting via bodies.

12. The module of claim 11, wherein the complementary signals include a first signal and a second signal.

13. The module of claim 12, wherein the first signal is a clock signal and the second signal is a clock bar signal.

14. The module of claim 12, further comprising:
a first diverging element configured to receive the first signal from one of the diverging bodies of the pair of diverging bodies;
a second diverging element configured to receive the second signal from the other diverging body of the pair of diverging bodies;
a first plurality of first conductive elements connected to the first diverging element; and
a first plurality of second conductive elements connected to the second diverging element.

15. The module of claim 14, wherein a topology of the circuit board is symmetric and the first and second diverging elements and the first plurality of first conductive elements and the first plurality of second conductive elements are on a first layer.

16. The module of claim 15, further comprising:
a first plurality of signal lines connecting the first plurality of first conductive elements to the first diverging element; and
a second plurality of signal lines connecting the first plurality of second conductive elements to the second diverging element, wherein the first plurality of signal lines and the second plurality of signal lines form a symmetric pattern on the first layer.

17. The module of claim 14, further comprising:
a third diverging element configured to receive the first signal and transmit the first signal to the first diverging element;
a fourth diverging element configured to receive the second signal and configured to transmit the second signal to the second diverging element;
a second plurality of first conductive elements connected to the first plurality of first conductive elements; and
a second plurality of second conductive elements connected to the first plurality of second conductive elements.

18. The module of claim 17, wherein the third diverging element, the fourth diverging element, the second plurality of first conductive elements, and the second plurality of second conductive elements are on a layer other than from the first layer.

19. The module of claim 17, wherein the third diverging element, the fourth diverging element, the second plurality of first conductive elements, and the second plurality of second conductive elements are on a second layer.

20. The module of claim 17, wherein the at least three pairs of connecting vias connects the first plurality of first conductive elements to the second plurality of first conductive elements and the first plurality of second conductive elements to the second plurality of second conductive elements.
